(19) United States
(12) Patent Application Publication
(10) Pub. No.: US 2013/0160183 A1
(43) Pub. Date: Jun. 27, 2013

(54) TEXTILE ARRANGEMENT AND METHOD FOR MANUFACTURING

(71) Applicants: Akseli Reho, Kankaanpaa (FI); Heikki Jaakkola, Kankaanpaa (FI); Antti Perko, Lahti (FI)

(72) Inventors: Akseli Reho, Kankaanpaa (FI); Heikki Jaakkola, Kankaanpaa (FI); Antti Perko, Lahti (FI)

(21) Appl. No.: 13/336,944

(22) Filed: Dec. 23, 2011

(51) Int. Cl. A41D 1/00; H01P 11/00; H05K 3/02; H05K 3/10; A42B 1/04; A41B 1/00; A41D 1/06; A43B 17/00; A41D 20/00; A41F 9/00; A43B 1/00; A41D 23/00; A41D 19/00; A41D 25/00; H05K 1/03; H05K 3/32

(52) U.S. Cl. 2/69; 29/832; 29/601; 2/171; 2/227; 2/239; 2/170; 2/336; 36/83; 2/207; 2/159; 2/144; 174/254

(57) ABSTRACT

A textile arrangement that includes at least one flexible circuit board integrated with a textile and a fixedly-integrated electronic component in the flexible circuit board. The flexible circuit board includes a flexible and/or tensile substrate, which is configured to bend and/or stretch at least in one direction. In addition, the flexible circuit board includes at least one electrically-conducting trace, at least one end of the trace being coupled with the component. The electrically-conducting trace is configured to bend and/or stretch with the flexible and/or tensile substrate of the circuit board at least in said one direction, when the circuit board is bent and/or stretched.

### TECHNICAL FIELD OF THE INVENTION

The invention relates to a textile arrangement and a method for manufacturing said textile arrangement. In particular the invention relates to a textile arrangement comprising a fixedly integrated electronic component, such as e.g. an LED light, sensor, button, antenna or display.

### BACKGROUND OF THE INVENTION

Textiles and garments may comprise integrated electronic components, such as sensors, antennas, LED lights, radio transceivers and control buttons. The components are typically connected with each other or data processing means by electrically-conducting cables or wires, which are integrated into the textile or garment. The use of electrically-conducting textile fibers in the textiles or garments is also known from prior art.

There are however some disadvantages relating to implementation of electrically-conducting guidance between the components in the known prior art methods, namely, for example, sewing electrically-conducting cables or wires into the textile or garment is slow and not an easy or a cost-effective process. In addition, integrated wires or conducting fibers in the textile or garment are not reliable due to, e.g., movements of a garment, rubbing, humidity and perspirations as well as washing, which typically have many negative effects into the signal guidance between the components. Furthermore implementation of a reliable and miniature joint and connection technique for detachably attached electronic components is a very challenging task in textiles and garments due to their interfering environments. The reliability, durability, protection and connectivity of the electrically-conducting cables or wires are especially poor. In addition the electrical properties of the electrically-conducting textile fibers are typically insufficient to guide electrically very weak signals reliably in an electrically interfering environment. Still, in addition the durability of the very thin conductors, cables or wires integrated into the textiles or garments is insufficient in a mechanically interfering environment, but on the other hand thicker wires or cables would not be comfortable in use.

### SUMMARY OF THE INVENTION

An object of the invention is to alleviate and eliminate the problems relating to the known prior art. Especially the object of the invention is to provide an arrangement, which can be easily applied with textiles and garments for guiding electrically very weak signals in a reliable manner in mechanically, physically, chemically and electrically interfering environments.

The object of the invention can be achieved by the features of the claims.

The invention relates to a textile arrangement as well as to a method for manufacturing the textile arrangement or a garment.

According to an embodiment of the invention a textile arrangement or textile-comprising arrangement comprises one or more fixedly integrated electronic components, such as, e.g., an LED light, sensor, button, antenna or display, and sometime, a resistor, capacitor, diode, microcontroller, processor, or the like. In addition the arrangement may also comprise detachably attached components. However, according to the invention, the arrangement comprises at least one flexible circuit board integrated with the textile for comprising said at least one fixedly integrated electronic component.

The flexible circuit board (that may be, according to an embodiment of the invention, a printed circuit board) advantageously comprises a flexible and/or tensile substrate, which is configured to bend and/or stretch at least in one direction. In addition the flexible circuit board also comprises one or more electrically-conducting traces extending along the circuit board so that when the flexible and/or tensile substrate of the circuit board is bent and/or stretched, the trace will bend and/or stretch together with said substrate. The trace is advantageously implemented so that at least one end, or other point of it, is coupled with the integrated electronic component. In addition, the electrically-connecting traces may be protected by lacquer or the like, or otherwise coated in order to create an electrical insulation over the trace and also against the external interactions, such as chemical and mechanical interactions. Furthermore, the circuit board can be covered with textile layer(s) so that circuit board locates between the textile layers, whereupon the textile layers both protect the circuit board and its components and traces, as well as make it much more comfortable to use for example in connection with garments.

Due to the flexible circuit board having flexible and/or tensile substrate and flexible and/or tensile conducting trace the invention offers remarkable advantages, namely the electrically-conducting trace applied, e.g., on the surface of the substrate does not perish as easily as bare conductors or wires. In addition, the circuit board offers good support and a base for the components, whereupon they will not fall away or be released so easily from their connections.

According to an exemplary embodiment, the electrically-conducting trace can be made bendable and/or stretchable by manufacturing it from a stretchable material, like silicone, which is advantageously doped by electrically-conducting particles, such as by silver or carbon particles. Of course, also other conducting particles, as well also other base stretching material other than silicone, can be used. In addition, the bendable/stretchable trace can be implemented by corrugating it, e.g., on the surface of the substrate, whereupon when bending or stretching said circuit board, the corrugated trace will straighten out and thereby allow the trace to bend or stretch together with said circuit board without breaking, perishing or getting cut off.

According to an embodiment, the flexible and/or tensile substrate of the flexible circuit board may be made at least partly of flexible and/or tensile material. It may comprise, e.g., polyimide, PEN or PET material, silicone film, or plastic film, or any other appropriate flexible and/or tensile material comprising film. The flexible circuit board may also be provided with cuttings or corrugated portions where the flexible circuit board is configured to bend and/or change its shape when applying shear stress to said circuit board structure and thereby enabling said flexible circuit board.

According to an embodiment the textile arrangement or flexible circuit board may further comprise an electrically-conducting means for electronic components to be detachably attached, such as a power source, data processing unit, or a communication unit, but possibly also other connectors or cables. The electrically-conducting means may be implemented, e.g., by providing an electrically-conducting area, surface, joint, pad, connector, spring connector or pin, or the like, applied to the circuit board. Advantageously, said electrically-conducting means is coupled at least with one end with the electrically-conducting trace of the circuit board. Via the electrically-conducting means, the components can also be attached in a detachable manner, whereupon they can be removed from the arrangement, for example, before washing or other repairing task of said textile or garment. For example, data processing units or other costly electronic units should be removable, whereupon the garments according to the embodiment of the invention may be manufactured and sold without said costly electronics, whereupon they can be attached in a detachable way and at the end of the garment's life cycle they can be removed and attached again to the next garment, for example.

It is to be noted that the fixedly integrated electrical components may be attached (or integrated) into the circuit board (or its electrically-conducting means, such as joints or pads), for example, by soldering, gluing, pressing, casting or welding. In addition, the electrically-conducting means may be a leading-in connection means, which is applied through said circuit board so that the components or other traces can be applied on the other side of the circuit board and electrically connect to the first side via said leading-in connection means.

According to an embodiment, the electrically-conducting trace, as well as fixedly-integrated electronic components (especially when being a passive component, such as an antenna or sensor), is advantageously implemented by utilizing subtractive and/or additive methods known from the prior art of the circuit board manufacturing industry, such as for example, by etching, printing, screen printing, silk-screen printing, dispensing or casting electrically-conducting media on/in the surface of the circuit board. One very good example is a silk-screen printing technique, which is a cost effective, fast and reliable method especially for large areas.

According to an advantageous embodiment, a portion of said electrically-conducting trace is configured to form at least part of said fixedly-integrated electronic component, especially when functioning as a passive component. For example, the properties of the portion of said trace forming at least part of said fixedly integrated electronic component differs from the corresponding properties of other portion of said trace, such as width, thickness, conductivity or shape, whereupon the component forming portion of said trace may function as an antenna or sensor, for example. This is a very cost effective and fast way to provide the arrangement with reliably working electrical components. In addition additional joints or junctions, and thereby also additional working phases and additional components, can be avoided.

In addition, according to an embodiment, the circuit board may also comprise a reinforcement portion, which mechanically supports a certain area of the flexible, bending and/or stretching area of the circuit board, such as especially the area of the fixedly integrated electronic component, where the components should not be exposed to bend or stretch.

An exemplary embodiment of the invention relates to a garment, which comprises, or is made of, the textile arrangement as discussed elsewhere in this document. The circuit board is advantageously integrated with the textile or garment, for example, by gluing, sewing, laminating or welding, but also other integration methods can be applied. The garment may be, for example, a cap, such as an EEG cap (electroencephalograph), shirt, trousers, sock, wristband, strap, belt, shoes, headscarf, wrap, glove, tie, outdoor clothing, or underclothing comprising an electronic component, such as a sensor, but not limited to those.

Furthermore, the invention relates to a method for manufacturing a textile arrangement or a garment as discussed elsewhere in this document. The method comprises integrating at least one flexible circuit board with the textile for example by gluing, sewing, laminating or welding, wherein said circuit board comprises flexible and/or tensile substrate, which is able to bend and/or stretch at least in one direction. In addition, at least one electronic component is fixedly integrated into the circuit board. The circuit board is also provided with one or more electrically-conducting traces, at least one end of which is coupled with said component. The trace advantageously bends and/or stretches with the circuit board when bent or stretched.

The present invention offers advantages over the known prior art, such as the ability to integrate a plurality of circuit boards as modules into the textile arrangements or garments. The invention further offers a mechanically durable, but at the same time very flexible and adaptive, platform to provide a textile arrangement for fixedly integrated electronic components in a reliable way in a very interfering environment. The arrangement according to the invention is mechanically durable against movements of a textile or garment, rubbing, humidity and perspirations, for example, but at the same time it offers sufficient ways to guide electrically very weak signals reliably in an electrically-interfering environment. Moreover, the textile arrangement with the circuit board(s) according to the invention is easy, fast and thereby very cost effective to manufacture. Furthermore, the circuit board(s) can even be manufactured in a first factory specialized, e.g., for manufacturing the circuit board(s), whereupon another factory, such as textile or garment specialized factory, can implement said circuit board(s) (possibly provided with electronic components) with their textile comprising arrangement, like garments.

### BRIEF DESCRIPTION OF THE DRAWINGS

Next the invention will be described in greater detail with reference to exemplary embodiments in accordance with the accompanying drawings, in which:

FIG. 1 illustrates an exemplary circuit board with an electrically-conducting trace according to an advantageous embodiment of the invention;

FIG. 2 illustrates examples of flexible circuit boards with electrically-conducting traces according to an advantageous embodiment of the invention;

FIG. 3 illustrates an exemplary flexible circuit board comprising an electrically-conducting trace forming an electronic component according to an advantageous embodiment of the invention;

FIG. 4 illustrates an exemplary textile arrangement with a flexible circuit board and an electrically-conducting trace according to an advantageous embodiment of the invention, and

FIG. 5 illustrates an exemplary garment according to an advantageous embodiment of the invention.

### DETAILED DESCRIPTION

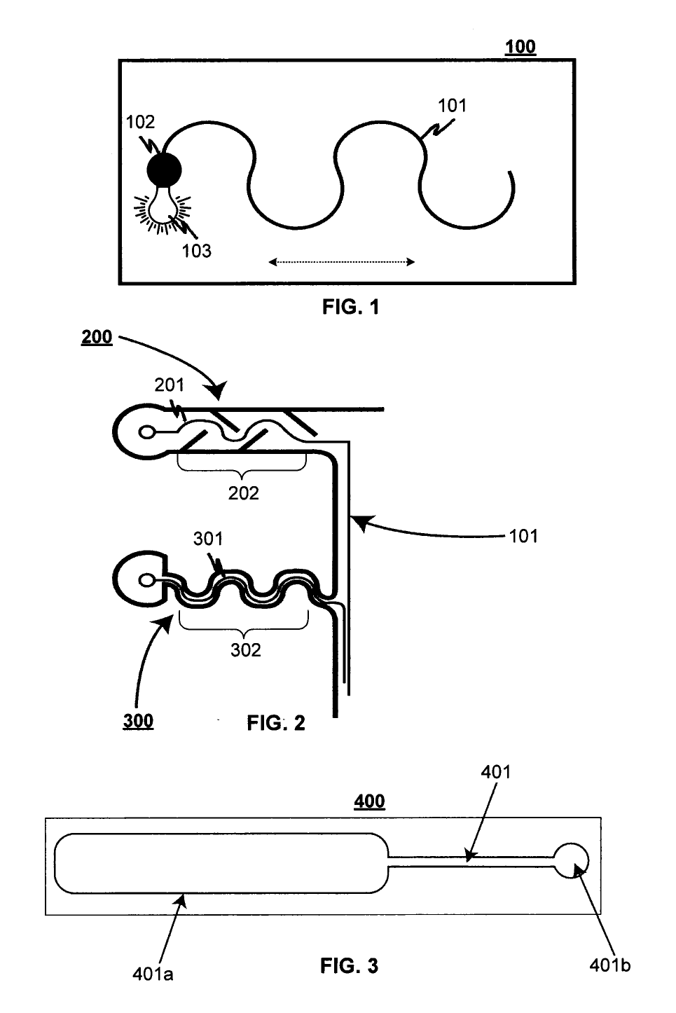

FIG. 1 illustrates an exemplary circuit board 100 with an electrically-conducting trace 101 according to an advantageous embodiment of the invention, where said circuit board is made of flexible and/or tensile substrate material and can thereby bend and/or stretch at least in one direction. The other end of the electrically-conducting trace is formed as a joint or pad 102, where a fixedly-integrated electronic component 103 is connected into the circuit board.

The electrically-conducting trace 101 is corrugated so that when the circuit board is bent and/or stretched, e.g., in the direction of the arrow, the corrugated trace 101 will be straightened out especially in the direction of the arrow, thereby allowing the trace to bend or stretch together with the circuit board without breaking, perishing or getting cut off.

FIG. 2 illustrates examples of flexible circuit boards 200, 300 with electrically-conducting traces according to an advantageous embodiment of the invention. The flexibility and/or stretchability of the circuit board 200 is achieved by applying cut, slit or split portions 202 to the substrate so that when the circuit board is bent/stretched the portions 202 allow deformation and thereby flexibility of said circuit board 200. The cut, slit or split portions 202 are applied into an angle in FIG. 2, but it is to be noted that they can be applied also essentially perpendicularly and possibly also in an overlapping manner, whereupon even more flexible and/or tensile structure can be achieved. The flexibility and/or stretchability of the circuit board 300 is in turn achieved by applying corrugated portions 302 to the substrate so that when the circuit board is bent/stretched, the portions 302 allow deformation and thereby flexibility of said circuit board 300.

Also, the electrically-conducting traces 201, 301 are corrugated as depicted in FIG. 2, enabling their stretchability together with the circuit boards 200, 300. It is however to be noted that the flexibility of the conducting traces 201, 301 can be achieved also via other methods described in this document, such as using stretchable material, like silicone, which is doped by electrically-conducting particles. In addition, it is to be noted that the ends of both traces 201, 301 are connected to an electrically-conducting means 203, 303, such as joints or pads.

FIG. 3 illustrates an exemplary flexible circuit board 400 according to an advantageous embodiment of the invention, wherein the circuit board comprises an electrically-conducting trace 401, the portion 401a of which forms a passive electronic component 401a, and another end of the trace forms an electrically-conducting means 401b, such as a pad or joint. The passive electronic component 401a may be, e.g., an antenna or sensor 401a, such as a sensor having an electrically-conducting surface contacting, e.g., the skin of the user, or as an antenna used in RFID technology. However, the invention is not limited to those.

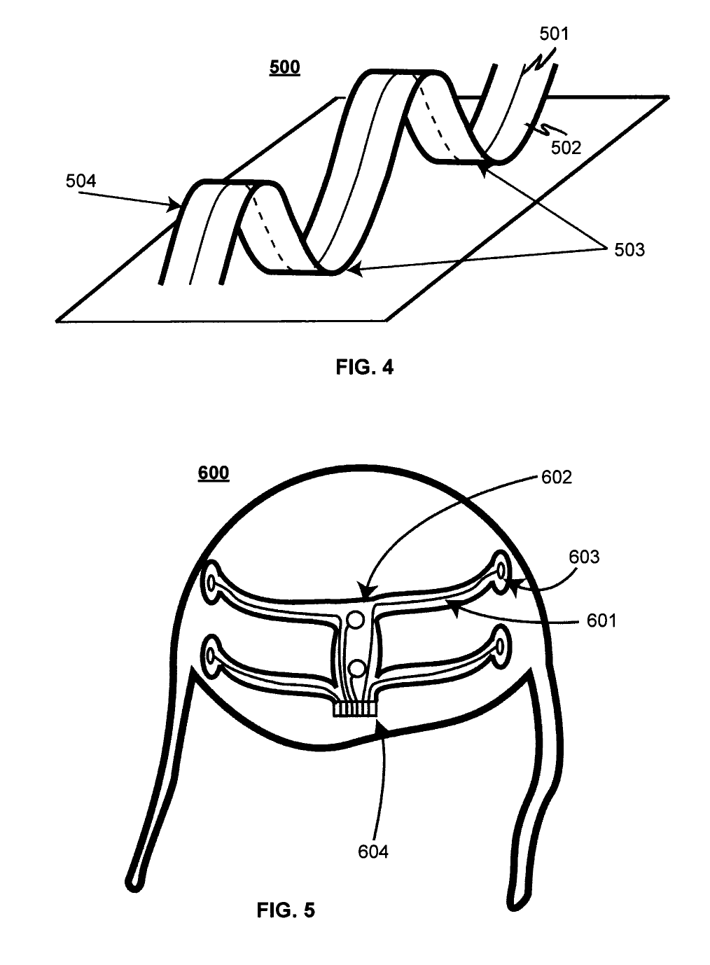

FIG. 4 illustrates an exemplary textile arrangement 500 with a flexible circuit board 502 and an electrically-conducting trace 501, according to an advantageous embodiment of the invention, wherein said circuit board can be integrated with the textile 500, for example, by gluing, sewing, laminating or welding from the attaching points 503. The stretchability of said circuit board together with the textile arrangement 500 (such as a garment) is achieved by attaching said circuit board to the textile via said attaching points 503 so that the flexible circuit board forms corrugations 504 in the direction where it is bent and/or stretched with said textile.

FIG. 5 illustrates an exemplary garment 600 according to an advantageous embodiment of the invention, wherein said garment comprises at least one of the flexible circuit boards 602, which is advantageously similar as described in connection with the other figures, or elsewhere in this document, and comprising electrically-conducting traces 601 as well as fixedly-integrated electronic components 603. The garment 600 or its circuit board 602 may also comprise an electrically-conducting means 604 for detachably attaching an electronic component, such as attaching external electronic components, such as a power source or communication unit, or the like.

The invention has been explained above with reference to the aforementioned embodiments, and several advantages of the invention have been demonstrated. It is clear that the invention is not restricted to these embodiments, but comprises all possible embodiments within the spirit and scope of the inventive thought and the following patent claims. For example, the textile or garment may comprise a plurality of flexible circuit boards coupled with each other, e.g., via their electrically-conducting means either in a detachable or fixed manner. In addition, the circuit board, and thus the textile arrangement and/or garment, may comprise numbers of different electronic components, both fixedly integrated and detachably attached. In addition, it is to be noted that the flexible circuit boards can be covered by textile in order to hide said circuit boards in the garment, for example. Also the electronic components may be any electronic component and the invention is not limited to those mentioned in this document.

We claim:

1. A textile comprising arrangement comprising at least one fixedly-integrated electronic component, comprising:
at least one flexible circuit board integrated with a textile, and wherein the flexible circuit board comprises:
flexible and/or tensile substrate configured to bend and/or stretch at least in one direction,
at least one fixedly-integrated electronic component, and
at least one electrically-conducting trace, at least one end of said trace being coupled with said fixedly-integrated component, and wherein said electrically-conducting trace is configured to bend and/or stretch with said flexible and/or tensile substrate of the circuit board at least in said one direction.

2. The textile arrangement of claim 1, wherein said electrically-conducting trace is configured to bend and/or stretch by implementing it from the stretching material, like silicone, doped by electrically-conducting particles, such as silver or carbon particles, and/or by corrugating it at least in said one direction.

3. The textile arrangement of claim 1, wherein the flexible circuit board comprises cut or corrugated portions where the flexible circuit board is configured to bend and/or change its shape when applying shear stress to said circuit board structure.

4. The textile arrangement of claim 1, wherein said textile arrangement or flexible circuit board further comprises an electrically-conducting means for detachably attaching an electronic component, such as a power source, data-processing unit, or communication unit, said electrically-conducting means being coupled with the electrically-conducting trace of said circuit board.

5. The textile arrangement of claim 1, wherein said electrically-conducting trace and/or fixedly integrated electronic component when being a passive component, such as an antenna or sensor, is implemented by subtractive and/or additive methods, such as etching, printing, screen printing, silk screen printing, dispensing or casting electrically-conducting media on/in the surface of the circuit board.

6. The textile arrangement of claim 1, wherein a portion of said electrically-conducting trace is configured to form at least part of said fixedly integrated electronic component, when being a passive component, such as an antenna or sensor.

7. The textile arrangement of claim 6, wherein properties of the portion of said trace forming at least part of said fixedly-integrated electronic component differs from the corresponding properties of either portion of said trace, such as width, thickness, conductivity or shape.

8. The textile arrangement of claim 1, wherein said circuit board comprises reinforcement portions configured to support the area of said fixedly integrated electronic component of the flexible circuit board.

9. The textile arrangement of claim 1, wherein said circuit board is integrated with the textile by gluing, sewing, laminating or welding.

10. A garment, comprising or made of a textile arrangement of any of claim 1, wherein said garment is one of the following: cap, such as an electroencephalograph (EEG) cap, shirt, trousers, sock, wristband, strap, belt, shoes, headscarf, wrap, glove, tie, outdoor clothing, mid-layer clothing or underclothing, comprising an electronic component, such as a sensor.

11. A method for manufacturing a textile arrangement or a garment, comprising:
integrating at least one flexible circuit board with the textile by gluing, sewing, laminating or welding, wherein said circuit board comprises flexible and/or tensile substrate configured to bend and/or stretch at least in one direction,
providing the circuit board with at least one fixedly integrated electronic component, and
providing the circuit board with at least one electrically-conducting trace, coupling at least one end of said trace with said component, and configuring said electrically-conducting trace to bend and/or stretch with said flexible and/or tensile substrate of the circuit board at least in said one direction.

12. The method of claim 11, further comprising a step of implementing said electrically-conducting trace from the stretching material, like silicone, doped by electrically-conducting particles, such as silver or carbon particles, and/or corrugated said trace at least in said one direction.

13. The method of claim 11, further comprising a step of providing the flexible circuit board by cut or corrugated portions so that the flexible circuit board bends or changes its shape when applying shear stress to said circuit board structure in the area of said cut or corrugated portions.

14. The method of claim 11, further comprising a step of implementing said electrically-conducting trace and/or fixedly-integrated electronic component when being a passive component, such as an antenna or sensor, by subtractive and/or additive methods, involving etching, printing, screen printing, silk-screen printing, dispensing or casting, electrically-conducting media on or into a surface of the circuit board.

15. The method of claim 11, further comprising a step of configuring a portion of said electrically-conducting trace to form at least part of said fixedly integrated electronic component, when being a passive component, such as an antenna or sensor.
